(19) United States
(12) Patent Application Publication
(10) Pub. No.: US 2006/0145263 A1
(43) Pub. Date: Jul. 6, 2006

(54) Plasma damage protection circuit for protecting multiple word lines or strapped word lines of a memory device

(75) Inventor: Ming-Hung Chou, Houlong Township (TW)

Correspondence Address: FINNEGAN, HENDERSON, FARABOW, GARRETT & DUNNER;LLP, 901 NEW YORK AVENUE, NW, WASHINGTON, DC, 20001-4413, US

(73) Assignee: Macronix International Co., Ltd.

(21) Appl. No.: 11/029,366

(22) Filed: Jan. 6, 2005

(51) Int. Cl. H01L 23/62

(52) U.S. Cl. 257/361

(57) ABSTRACT

A memory device is connectable to a protection circuit for plasma-induced charge damage protection and includes a memory array including a plurality of word lines and a plurality of diodes each coupled between a corresponding one of the word lines and the protection circuit.

### TECHNICAL FIELD

This invention is in general related to a protection circuit for protecting a semiconductor device from plasma damage.

### DESCRIPTION OF RELATED ART

During the fabrication of an integrated circuit (IC), metal or polysilicon lines are formed by plasma etching to interconnect devices of the IC. The plasma etching generally induces charges that are accumulated on the metal or polysilicon lines. Because of the relatively high capacitance of an MOS gate, the plasma-induced charges are accumulated in the gate of an MOS device and may tunnel into neighboring dielectrics. Similarly, if the IC includes certain devices with very thin dielectrics, a metal or polysilicon layer on the thin dielectrics is also likely to accumulate a proportion of the plasma-induced charges. Damage caused by the plasma-induced charges includes charge traps created in the dielectrics, deterioration of the interface of the dielectrics, shortening of device lifetime, etc. As a result, the performance of the IC, which may include a plurality of MOS devices or other devices having thin film dielectrics, is degraded.

Methods of protecting the IC from plasma damage during manufacturing processes have been proposed. For example, Chou et al. describes in U.S. Patent Application Publication No. 2004/0007730, a protection device comprising a pair of PMOS and NMOS transistors having their respective gate terminals coupled to their respective substrates. FIGS. 4-5 of U.S. Patent Application Publication No. 2004/0007730 are reproduced as FIGS. 1-2, respectively.

In FIG. 1, an IC device 10 formed on a device substrate 11 includes an IC 12 that is protected by a protective device composed of a PMOS transistor 15 and an NMOS transistor 16. One of the source/drain terminals of PMOS transistor 15 is grounded. The other of the source/drain terminals of PMOS transistor 15 is coupled to a node 14 of IC 12 to provide plasma damage protection. The gate of PMOS transistor 15 is coupled to the substrate of PMOS transistor 15 and is further coupled to receive a voltage generated by a voltage generator 13 during operation. One of the source/drain terminals of NMOS transistor 16 is grounded. The other of the source/drain terminals of NMOS transistor 16 is also coupled to node 14 to provide plasma damage protection. The gate of NMOS transistor 16 is coupled to the substrate of NMOS transistor 16 and is further coupled to receive a voltage from voltage generator 13 during operation.

During manufacturing, voltage generator 13 does not generate voltage outputs and the gates of PMOS transistor 15 and NMOS transistor 16 are floating. During operation of IC device 10, the voltage received by the gate of PMOS transistor 15 is the highest possible operating voltage of IC device 10 and the voltage received by the gate of NMOS transistor 16 is the lowest possible operating voltage of IC device 10, such that both PMOS transistor 15 and NMOS transistor 16 are turned off to avoid interference with the normal operations of IC device 10.

FIG. 2 is a cross-sectional view of PMOS transistor 15 and NMOS transistor 16 formed on a p-type semiconductor substrate 20 (PW). A first deep n-type well 21 (NWD) and a second deep n-type well 22 (NWD) are formed in substrate 20. PMOS transistor 15 has a source 23 and a drain 24 formed in first deep n-type well 21, which is the substrate of PMOS transistor 15, and a gate 27 formed over a channel region defined between source 23 and drain 24. An n-type contact region 25 is formed in the surface of first deep n-type well 21. A p-type contact region 26 is formed in the surface of substrate 20 (PW) adjacent to first deep n-type well 21. A deep p-type well 31 (PWI) is formed in second deep n-well 22. NMOS transistor 16 has a source 32 and a drain 33 formed in p-type well 31, which is the substrate of NMOS transistor 16, and a gate 36 formed over a channel region defined between source 32 and drain 33. An n-type contact region 37 is formed in the surface of second deep n-type well 22. A p-type contact region 34 is formed in the surface of p-type well 31. Also, a p-type contact region 35 is formed in the surface of the substrate 20 adjacent to second deep n-type well 22.

Gate 27 of PMOS transistor 15 is coupled to first deep n-type well 21 via contact region 25 and further coupled to receive a voltage VPCP11 generated by voltage generator 13 during operation, wherein VPCP11 is the highest operating voltage of IC device 10. Source 23 of PMOS transistor 15 is coupled to substrate 20 via contact region 26 and further to a ground reference. Drain 24 of PMOS transistor 15 is coupled to a node 30 (node 14 in FIG. 1) to be protected from plasma damage.

Gate 36 of NMOS transistor 16 is coupled to p-type well 31 via contact region 34 and further coupled to receive a voltage NVPP generated by voltage generator 13 during operation, wherein NVPP is the lowest operating voltage of IC device 10. Source 32 of NMOS transistor 16 is coupled to substrate 20 via contact region 35 and further to a ground reference. Drain 33 of NMOS transistor 16 is also coupled node 30 (node 14 in FIG. 1) to be protected from plasma damage.

During the manufacturing process of IC device 10, gates 27 and 36 are floating. Therefore, if there are positive charges accumulated on node 14 (node 30 in FIG. 2), the positive charges may be discharged through PMOS transistor 15. If there are negative charges accumulated on node 14 (node 30 in FIG. 2), the negative charges may be discharged through NMOS transistor 16.

However, when IC 12 is a memory array including a number of word lines that may be subject to plasma damage, the protective device of FIG. 1 may be inefficient because only one word line can be protected by that protective device. To protect the entire memory array, many of the protective devices of FIG. 1 must be used. As a result, a larger chip area is consumed.

Moreover, the protective device of FIG. 1 is not suitable for protecting strapped word lines. FIG. 3 shows a partial plan view of a conventional memory device 300 having strapped word lines. FIG. 4 shows a cross-sectional view of memory device 300 along line A-A′ of FIG. 3. Memory device 300 is formed on a semiconductor substrate 302 and includes a plurality of memory cells (not shown) arranged in a plurality of rows and a plurality of columns. Each row corresponds to a word line WL and each column corresponds to a bit line BL. Bit lines BL are formed of diffusion regions (not shown) in semiconductor substrate 302. Each word line WL comprises a top layer metal stripe 304 and a plurality of polysilicon segments 306. As shown in FIG. 4, each polysilicon segment 306 is coupled to top layer metal stripe 304, in a strapping area 308, through a first metal contact 310, a via 312 in an inter-metal dielectric (IMD) 314, and vias 316 and 318 in an inter-layer dielectric (ILD) 320. Polysilicon segments 306 are formed on a layer of gate dielectric 322, which in turn is provided on semiconductor substrate 302.

When the protective device of FIG. 1 is coupled to one polysilicon segment 306 of a word line WL, the protective device may properly discharge plasma-induced charges on that polysilicon segment 306. However, charges accumulated on other polysilicon segments 306 are not efficiently discharged.

### SUMMARY OF THE INVENTION

Consistent with embodiments of the present invention, there is provided a memory device connectable to a protection circuit for plasma-induced charge damage protection. The memory device includes a memory array including a plurality of word lines and a plurality of diodes each coupled between a corresponding one of the word lines and the protection circuit.

Consistent with embodiments of the present invention, there is also provided a circuit that includes a memory device, which further includes a memory array including a plurality of word lines and a plurality of diodes each coupled to a corresponding one of the word lines. The circuit further includes a protection circuit coupled to the diodes for protecting the word lines from plasma-induced charge damage.

Additional features and advantages of the invention will be set forth in part in the description which follows, and in part will be obvious from the description, or may be learned by practice of the invention. The features and advantages of the invention will be realized and attained by means of the elements and combinations particularly pointed out in the appended claims.

It is to be understood that both the foregoing general description and the following detailed description are exemplary and explanatory only and are not restrictive of the invention, as claimed.

### BRIEF DESCRIPTION OF THE DRAWINGS

The accompanying drawings, which are incorporated in and constitute a part of this specification, illustrate embodiments of the invention and, together with the description, serve to explain the features, advantages, and principles of the invention.

In the drawings,

FIG. 1 shows a conventional circuit having a protective device;

FIG. 2 is a cross-sectional view of the protective device of FIG. 1;

FIG. 3 shows a partial plan view of a conventional memory device having strapped word lines;

FIG. 4 shows a cross-sectional view of the conventional memory device of FIG. 3 along line A-A′;

FIG. 5 shows a partial plan view of a memory device having strapped word lines consistent with embodiments of the present invention;

FIG. 6 is a cross-sectional view of the memory device of FIG. 5 along line B-B′;

FIG. 7A is a cross-sectional view of a protection circuit consistent with embodiments of the present invention;

FIG. 7B shows an equivalent circuit of the protection circuit of FIG. 7A; and

FIG. 8 shows a configuration in which the protection circuit of FIGS. 7A-7B is used to protect the memory device of FIGS. 5-6.

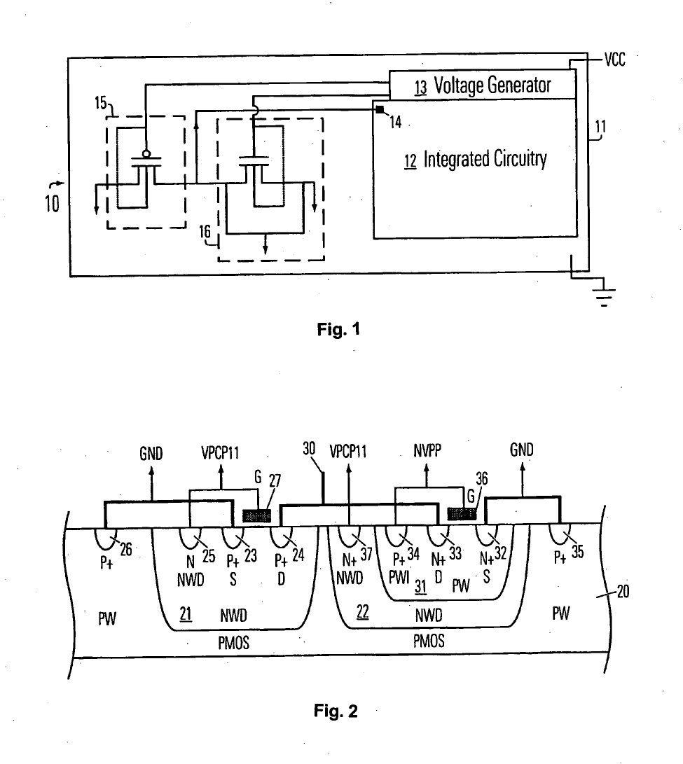

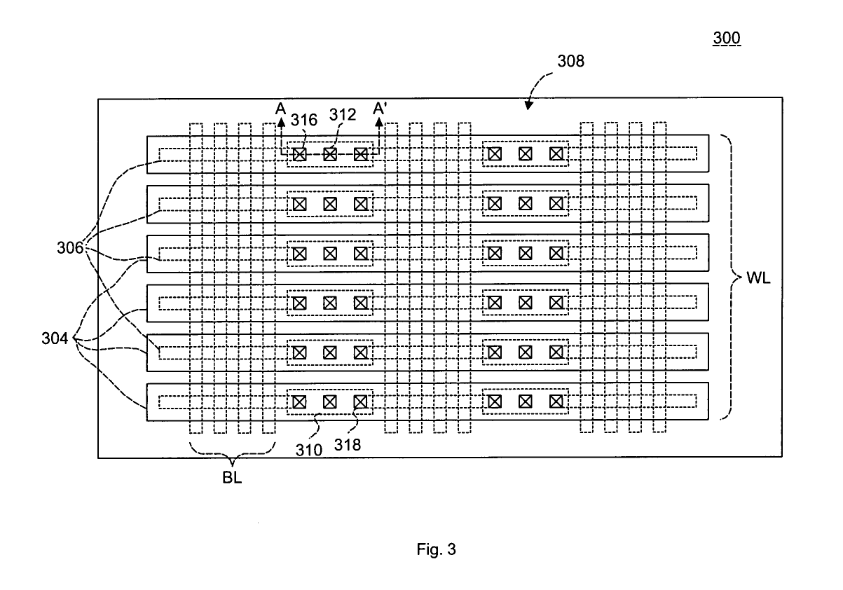

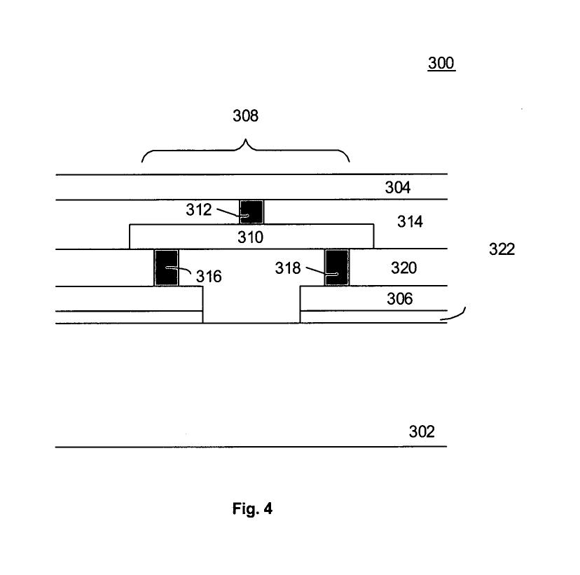

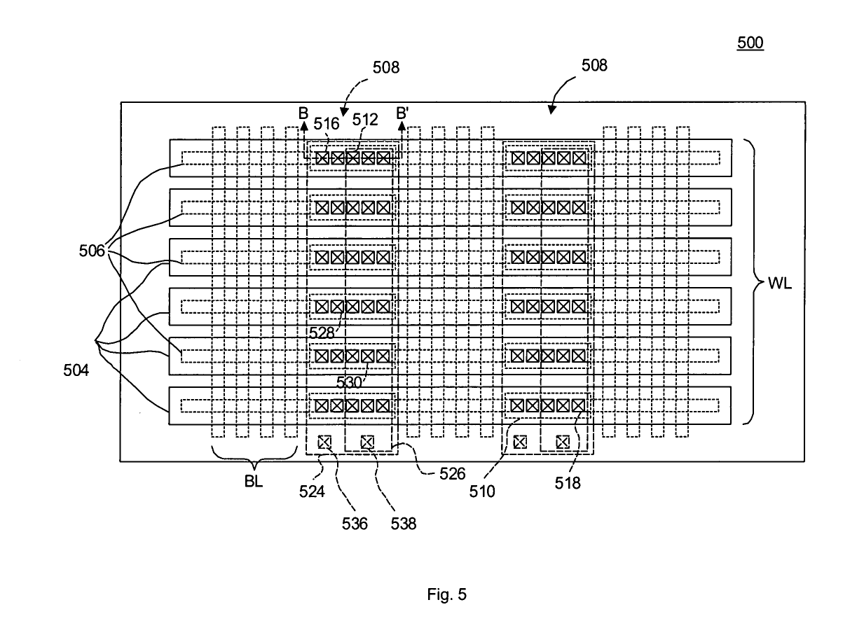

### DESCRIPTION OF THE EMBODIMENTS

Reference will now be made in detail to embodiments of the invention, examples of which are illustrated in the accompanying drawings. Wherever possible, the same reference numbers will be used throughout the drawings to refer to the same or like parts.

Consistent with embodiments of the present invention, there is provided a protection mechanism that provides protection from plasma-induced charge damage for multiple word lines or strapped word lines of a memory device.

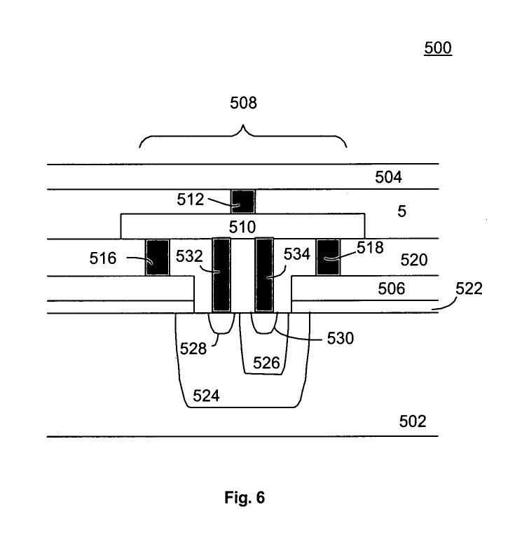

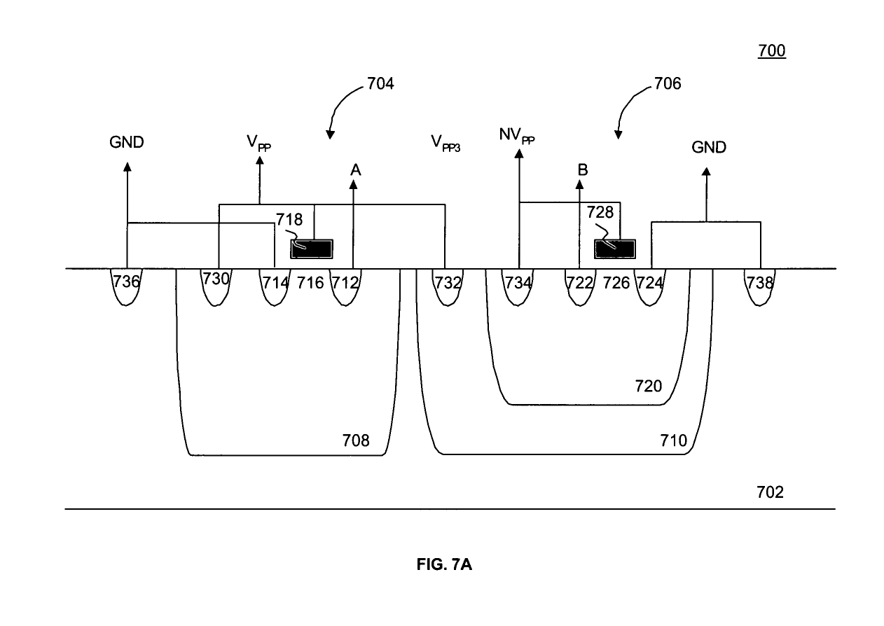

FIG. 5 shows a partial plan view of a memory device 500 having strapped word lines consistent with embodiments of the present invention. FIG. 6 shows a cross-sectional view of memory device 500 along line B-B′ of FIG. 5.

Memory device 500 is formed on a semiconductor substrate 502 and includes a plurality of memory cells (not shown) arranged in a plurality of rows and a plurality of columns. Each row corresponds to a word line WL and each column corresponds to a bit line BL. Bit lines BL are formed of diffusion regions (not shown) in semiconductor substrate 502. Each word line WL comprises a top layer metal stripe 504 and a plurality of polysilicon segments 506. As shown in FIG. 6, each polysilicon segment 506 is coupled to top layer metal stripe 504, in a strapping area 508, through a first metal contact 510, a via 512 in an inter-metal dielectric (IMD) 514, and vias 516 and 518 in an inter-layer dielectric (ILD) 520. Polysilicon segments 506 are formed on a layer of a gate dielectric 522, which in turn is provided on semiconductor substrate 502.

Consistent with the first embodiment of the present invention, there are also formed an n-type well 524 in strapping area 508 and a p-type well 526 in n-type well 524. Corresponding to each word line, there is a p⁺ diffusion region 528 formed in n-type well 524 and an n⁺ diffusion region 530 formed in p-type well 526. P⁺ diffusion region 528 is coupled to first metal contact 510 through a via 532 in ILD 520. N⁺ diffusion region 530 is coupled to first metal contact 510 through a via 534 in ILD 520.

Further, at one end of strapping area 508, an n⁺ diffusion region 536 serving as a well pick-up is formed in n-type well 524, and a p⁺ diffusion region 538 serving as a well pick-up is formed in p-type well 526. N⁺ diffusion region 536 is connectable to a protection circuit for discharging positive charges, and p⁺ diffusion region 538 is connectable to a protection circuit for discharging negative charges.

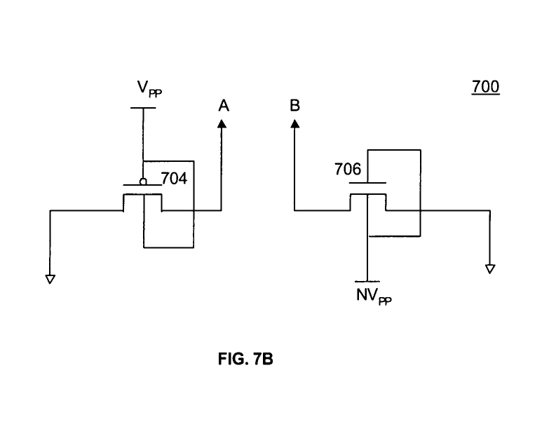

Consistent with embodiments of the present invention, there is also provided a protection circuit capable of discharging both positive and negative plasma-induced charges. FIG. 7A shows a cross-sectional view of a protection circuit 700 for discharging both positive and negative plasma-induced charges. FIG. 7B shows an equivalent circuit of protection circuit 700.

Protection circuit 700 is formed on a semiconductor substrate 702 and includes a PMOS transistor 704 and an NMOS transistor 706. A first deep n-type well (n-well) 708 and a second deep n-well 710 are formed in substrate 702. PMOS transistor 704 has a source 712 and a drain 714 formed in first deep n-well 708, which is the substrate of PMOS transistor 704, a channel region 716 defined between source 712 and drain 714, and a gate 718 over channel region 716. NMOS transistor 706 is formed in a p-type well (p-well) 720 provided in second n-well 710 and includes a source 722 and a drain 724 formed in p-well 720, which is the substrate of NMOS transistor 706, a channel region 726 defined between source 722 and drain 724, and a gate 728 over channel region 726.

Well pick-ups 730, 732, and 734 formed of heavily doped diffusion regions are respectively provided in first n-well 708, second n-well 710, and p-well 720. Well pick-ups 736 and 738 are provided in substrate 302, wherein well pick-up 736 is formed adjacent to first n-well 708, and well pick-up 738 is formed adjacent to second n-well 710.

Source 712 of PMOS transistor 704 is connectable to a node A of an external circuit for receiving and discharging positive charges. Source 722 of NMOS transistor 706 is connectable to a node B of the external circuit for receiving and discharging negative charges. Gate 718 of PMOS transistor 704 and well pick-ups 730 and 732 are all connectable to a voltage V_{PP}, where V_{PP} is the highest possible voltage on node A or the highest possible operating voltage of the external circuit. Gate 728 of NMOS transistor 706 and well pick-up 734 of p-well 720 are both connectable to a voltage NV_{PP}, where NV_{PP} is the lowest possible voltage on node B or the lowest possible operating voltage of the external circuit. Drains 714 and 724 are respectively coupled to well pick-ups 736 and 738 of substrate 702 and are further grounded. Therefore, during operation of the external circuit, PMOS transistor 704 and NMOS transistor 706 are turned off to avoid interference with the normal operations of the external circuit.

During the manufacturing process of the external circuit and protection circuit 700, gates 718 and 728 are floating. Therefore, if positive charges are accumulated on node A, a positive voltage appears at source 712 of PMOS transistor 704. As a result, PMOS transistor 704 is turned on to conduct current to discharge the positive charges on node A. If negative charges are accumulated on node B, a negative voltage appears at source 722 of NMOS transistor 706, which then turns on NMOS transistor 706 to conduct current to discharge the negative charges on node B.

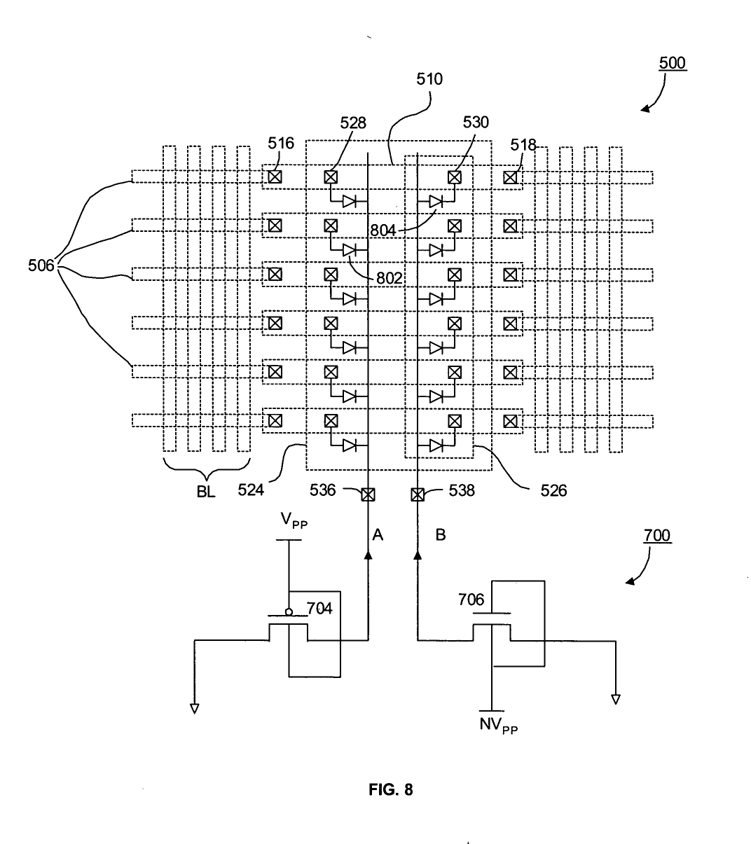

With reference to FIG. 8, Protection circuit 700 may be used to protect memory device 500 by coupling source 712 of PMOS transistor 704 to n-type well 524 through well pick-up 536 and coupling source 722 of NMOS transistor 706 to p-type well 526 through well pick-up 538. Thus, every word line WL and every polysilicon segment 506 are coupled to protection circuit 700 through two paths: 1) through first metal contact 510, via 532, a first diode 802 formed by the junction between p⁺ diffusion region 528 and n-type well 524, to source 712 of PMOS transistor 704; and 2) through first metal contact 510, via 534, a second diode 804 formed by the junction between n⁺ diffusion region 530 and p-type well 526, to source 722 of NMOS transistor 706. As shown in FIG. 8, each first diode 802 has a positive terminal coupled to a corresponding first metal contact 510 and, therefore, to the corresponding word line, and a negative terminal coupled to source 712 of PMOS transistor 704. Each second diode 804 has a positive terminal coupled to source 722 of NMOS transistor 706 and a negative terminal coupled to a corresponding first metal contact 510 and, therefore, to the corresponding word line. Thus, positive charges accumulated on a polysilicon segment 506 of a word line WL are discharged through the corresponding first diode 802 and PMOS transistor 704, and negative charges accumulated on a polysilicon segment 506 of a word line WL are discharged through the corresponding second diode 804 and NMOS transistor 706.

As discussed above, the protection mechanism consistent with embodiments of the present invention allow a single protection circuit to protect multiple word lines or strapped word lines of a memory device. Accordingly, chip area is saved.

It will be apparent to those skilled in the art that various modifications and variations can be made in the disclosed process without departing from the scope or spirit of the invention. Other embodiments of the invention will be apparent to those skilled in the art from consideration of the specification and practice of the invention disclosed herein. It is intended that the specification and examples be considered as exemplary only, with a true scope and spirit of the invention being indicated by the following claims.

What is claimed is:

1. A memory device connectable to a protection circuit for plasma-induced charge damage protection, the memory device comprising:
a memory array including a plurality of word lines; and
a plurality of diodes each coupled between a corresponding one of the word lines and the protection circuit.

2. The device of claim 1, wherein the protection circuit includes a first part for discharging positive charges and a second part for discharging negative charges, wherein the plurality of diodes include a plurality of first diodes each coupled between a corresponding one of the word lines and the first part of the protection circuit and a plurality of second diodes each coupled between a corresponding one of the word lines and the second part of the protection circuit.

3. The device of claim 2, wherein the each of the first diodes and the second diodes has a positive terminal and a negative terminal, wherein the positive terminal of each first diode is coupled to the corresponding word line and the negative terminal of each first diode is coupled to the first part of the protection circuit, and wherein the negative terminal of each second diode is coupled to the corresponding word line and the positive terminal of each second diode is coupled to the second part of the protection circuit.

4. The device of claim 3, wherein the memory device is formed on a semiconductor substrate, and each first diode is composed of an n-type well provided in the semiconductor substrate and a p-type diffusion region in the n-type well.

5. The device of claim 4, wherein each second diode is composed of a p-type well provided in the n-type well and an n-type diffusion region in the p-type well.

6. The device of claim 3, wherein the memory device is formed on a semiconductor substrate, and each second diode is composed of a p-type well provided in the semiconductor substrate and an n-type diffusion region in the p-type well.

7. The device of claim 1, wherein each of the plurality of word lines comprises a top layer metal stripe and a plurality of polysilicon segments, each polysilicon segment being coupled to the corresponding top layer metal stripe in a strapping area through a corresponding one of a plurality of first metal contacts.

8. The device of claim 7, wherein the plurality of diodes are formed in the strapping area and are coupled between the first metal contacts and the protection circuit.

9. A circuit, comprising:
a memory device, including
a memory array including a plurality of word lines, and
a plurality of diodes each coupled to a corresponding one of the word lines; and
a protection circuit coupled to the diodes for protecting the word lines from plasma-induced charge damage.

10. The circuit of claim 9, wherein the protection circuit includes a first part for discharging positive charges and a second part for discharging negative charges, wherein the plurality of diodes include a plurality of first diodes each coupled between a corresponding one of the word lines and the first part of the protection circuit and a plurality of second diodes each coupled between a corresponding one of the word lines and the second part of the protection circuit.

11. The circuit of claim 10, wherein each of the first diodes and the second diodes has a positive terminal and a negative terminal, wherein the positive terminal of each first diode is coupled to the corresponding word line and the negative terminal of each first diode is coupled to the first part of the protection circuit, and wherein the negative terminal of each second diode is coupled to the corresponding word line and the positive terminal of each second diode is coupled to the second part of the protection circuit.

12. The circuit of claim 11, wherein the memory device is formed on a semiconductor substrate, and each first diode is composed of an n-type well provided in the semiconductor substrate and a p-type diffusion region in the n-type well.

13. The circuit of claim 12, wherein each second diode is composed of a p-type well provided in the n-type well and an n-type diffusion region in the p-type well.

14. The circuit of claim 11, wherein the memory device is formed on a semiconductor substrate, and each second diode is composed of a p-type well provided in the semiconductor substrate and an n-type diffusion region in the p-type well.

15. The circuit of claim 9, wherein each of the plurality of word lines comprises a top layer metal stripe and a plurality of polysilicon segments, each polysilicon segment being coupled to the corresponding top layer metal stripe in a strapping area through a corresponding one of a plurality of first metal contacts.

16. The circuit of claim 15, wherein the plurality of diodes are formed in the strapping area and are coupled between the first metal contacts and the protection circuit.

17. The circuit of claim 9, wherein the protection circuit comprises:
a PMOS transistor including a gate, a source, a drain, and a substrate coupled to the gate of the PMOS transistor, the drain of the PMOS transistor for coupling to ground, and the source of the PMOS transistor being coupled to ones of the plurality of diodes, and
an NMOS transistor including a gate, a source, a drain, and a substrate coupled to the gate of the NMOS transistor, the drain of the NMOS transistor for coupling to ground, and the source of the NMOS transistor being coupled to other ones of the plurality of diodes.

18. The circuit of claim 17, wherein the gate of the PMOS transistor is coupled to receive a highest possible operating voltage of the memory device, and the gate of the NMOS transistor is coupled to receive a lowest possible operating voltage of the memory device.

19. The circuit of claim 17, wherein the source of the PMOS transistor is coupled to negative terminals of the ones of the diodes and the PMOS transistor is turned on to discharge positive charges when the positive charges are accumulated on the word lines.

20. The circuit of claim 17, wherein the source of the NMOS transistor is coupled to positive terminals of the other ones of the diodes and the NMOS transistor is turned on to discharge negative charges when the negative charges are accumulated on the word lines.
